(19) United States
(12) Patent Application Publication
(10) Pub. No.: US 2008/0224282 A1
(43) Pub. Date: Sep. 18, 2008

(54) Semiconductor device and method of manufacturing the same

(75) Inventors: Kisho Ashida, Hitachinaka (JP); Kenya Kawano, Hitachinaka (JP); Akira Muto, Takasaki (JP); Ichio Shimizu, Tamamura (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Renesas Technology Corp., Tokyo (JP)

(21) Appl. No.: 12/011,397

(22) Filed: Jan. 25, 2008

(30) Foreign Application Priority Data
Mar. 13, 2007 (JP) 2007-63132

(51) Int. Cl. H01L 23/495; H01L 21/56

(52) U.S. Cl. 257/669; 438/119; 257/E21.502; 257/E23.051

(57) ABSTRACT

A technique for preventing cracks and residual resin on a semiconductor chip in a molding process in the assembly of semiconductor devices is provided. A distance from a bottom surface of a cavity of a lower mold die to a ceiling surface of a cavity of an upper mold die of a resin molding die is made same as or smaller than a distance from a lower surface of a die pad to an upper surface of a plate terminal, and an U-shape elastic body is arranged on semiconductor elements between the plate terminal and the die pad, thereby mitigating a load due to a clamp pressure of mold dies in the molding process by an elastic deformation of the elastic body. Consequently, a load applied on the semiconductor devices is reduced, thereby preventing formation of cracks on the semiconductor elements.

### CROSS-REFERENCE TO RELATED APPLICATION

The present application claims priority from Japanese Patent Application No. JP 2007-063132 filed on Mar. 13, 2007, the content of which is hereby incorporated by reference into this application.

### TECHNICAL FIELD OF THE INVENTION

The present invention relates to a technique for a semiconductor device and a method of manufacturing thereof. More particularly, the present invention relates to a technique effectively applied to a semiconductor device of high thermal performance and assembly thereof.

### BACKGROUND OF THE INVENTION

As a semiconductor module having a double-sided cooling structure, there is a disclosure of a structure in which two semiconductor devices are formed in one package and each of the devices are sandwiched by a metal having a good thermal conductivity (e.g., copper and aluminum) (e.g., see Japanese Patent Application Laid-Open Publication No. 2006-120970 (Patent Document 1)).

In addition, there is a disclosure of a structure in which metal plates in a plate-shape are arranged on the front-back both sides of a semiconductor device (e.g., see Japanese Patent Application Laid-Open Publication No. 2004-228461 (Patent Document 2)).

### SUMMARY OF THE INVENTION

Power semiconductor devices such as the IGBT (Insulated Gate Bipolar Transistor) used for power control of vehicles have very large amount of heat release in use and thus a technique for improvement of heat transfer is essential.

Consequently, as a package structure for realizing improvement of heat transfer (or reduction of thermal resistance) of semiconductor devices (semiconductor chips), there has been considered a structure in which a conductive member having a large thermal conductivity is connected to both upper and bottom surfaces of a semiconductor chip and exposing the conductive member from a resin sealing body of the package. According to this structure, the heat generated in the semiconductor chip is transferred to the conductive member and the heat is radiated from the exposed surface of the conductive member to the outside of the semiconductor device. As an example of such a double-sided cooling structure, there is the above-mentioned Patent Document 1. The above-mentioned Patent Document 1 describes a structure in which two semiconductor devices are assembled in one package and each of the semiconductor devices is sandwiched by a metal having a good thermal conductivity (e.g., copper alloy and aluminum).

However, there are some problems to consider in the above-described double-sided cooling structure.

First, a comparative example of FIG. 29 shows a cross-sectional view of a semiconductor device using a common double-sided cooling structure after an assembling process thereof. In the assembling process, a die pad 5 and a clip 6 which are two plate-shape conductive members are connected to semiconductor devices 1a and 1b via an adhesive 7. And, the clip 6 is connected to an outer lead 17 which is an external electrode via the adhesive 7. Herein, a height L1 from a bottom surface 5b of the die pad 5 to an upper surface 6a of the clip 6 has a height variation according to variations in the process precision of the clip 6 and the thickness of the adhesive 7.

Next, a comparative example of FIG. 30 shows a cross-sectional view of a molding process in the assembly of the above semiconductor device. The semiconductor device after the assembly is applied a clamp pressure thereto being sandwiched by an upper mold die 2 and a lower mold die 3 and subjected to resin sealing by injecting a resin 12 to the inside thereof.

Here, a distance L2 from a bottom surface 3b of a cavity 3a of the lower mold die 3 to a ceiling surface 2b of a cavity 2a of the upper mold die 2 is constant. Therefore, when the height L1 of the semiconductor device after the assembly is larger than the distance L2, the clamp pressure given by the mold dies is loaded to the semiconductor device 1a or 1b via the die pad 5 and the clip 6, thereby increasing a possibility of causing cracks on the semiconductor devices 1a, 1b.

Further, when the height L1 is smaller than the distance L2, as shown in a comparative example of FIG. 31, the resin 12 gets around an upper surface 6a of the clip 6 so that a possibility of not exposing the clip 6 from the upper surface of the package is increased. In this manner, in the molding process, there is a problem of a possibility of frequently occurring product failures due to cracks of the semiconductor devices 1a, 1b and the residual resin.

Still further, in the case of the structure of the comparative example of FIG. 29, since the clip 6 to be exposed from the upper surface of the package is directly connected to the semiconductor device 1a or 1b, when a shape change in thickness and the like of the semiconductor devices 1a and 1b is made, it arises a necessity to change the shape of the clip 6, such as its thickness. The shape of the clip 6 is generally complicated because it often involves bending and etching processes. Therefore, it is a problem that designing the shape of the clip in every change of shape of the semiconductor device 1a or 1b requires a large amount of time and cost.

Moreover, as another structure in which plate-shape metal plates are arranged at front-back both sides of a semiconductor device, the above-mentioned Patent Document 2 discloses the structure. In the structure disclosed in Patent Document 2, a wiring portion of lead-out electrodes which is the metal plate arranged at a front surface side (upper side) of the semiconductor device is formed in one associated between devices as shown in FIG. 1 and FIG. 4. In such a structure, when a change in the shape of the semiconductor device is needed such as its thickness, it is required to make a design change on the shape of the draw-out electrode wiring part. As described above, the shape of the draw-out electrode wiring part which often involves bending and etching processes is complicated and thus it is a problem that making a change in design of the draw-out electrode wiring part in every shape change of the semiconductor device needs a large amount of time and cost.

An object of the present invention is to provide a technique for preventing cracks and residual resin of a semiconductor chip in a molding process in assembly of a semiconductor device.

Further, another object of the present invention is to provide a technique capable of completing a design change of a semiconductor device easily and inexpensively also when a design change on the shape of a semiconductor device is made.

The above and other objects and novel characteristics of the present invention will be apparent from the description of this specification and the accompanying drawings.

The typical ones of the inventions disclosed in this application will be briefly described as follows.

More specifically, the present invention comprises: a semiconductor chip having a main surface and a back surface on which electrodes are formed respectively; a back-surface-side plate member having the semiconductor chip mounted thereon and connected to the electrode of the back surface of the semiconductor chip via a conductive adhesive; a conductive elastic body arranged on the main surface of the semiconductor device and connected to the electrode of the main surface via the conductive adhesive; a main-surface-side plate member arranged on the elastic body and connected to the elastic body via the conductive adhesive; and a sealing body for sealing the semiconductor chip, the elastic body, the back-surface-side plate member and the main-surface-side plate member, in which the main-surface-side plate member is exposed from a ceiling surface of the sealing body and also the back-surface-side plate member is exposed from a bottom surface of the sealing body, and the elastic body is arranged so as to cause an elastic deformation to a thickness direction of the semiconductor chip.

Further, the present invention comprises: a semiconductor chip having a main surface and a back surface on which electrodes are formed respectively; a back-surface-side plate member having the semiconductor chip mounted thereon and connected to the electrode of the back surface of the semiconductor chip via a conductive adhesive; a conductive elastic body including opposing one and the other flat surfaces and a bending part coupling the opposing one and the other flat surfaces and arranged on the main surface of the semiconductor chip, and the one flat surface is connected to the electrode of the main surface of the semiconductor chip via the conductive adhesive; a main-surface-side plate member arranged on the elastic body and connected to the other flat surface of the elastic body via the conductive adhesive; and a sealing body for sealing the semiconductor chip, the elastic body, the back-surface-side plate member and the main-surface-side plate member, in which the main-surface-side plate member is exposed from a ceiling surface of the sealing body and the back-surface-side plate member is exposed from a bottom surface of the sealing body, and also the elastic body is arranged so as to cause an elastic deformation to a thickness direction of the semiconductor chip.

Moreover, the present invention comprises the steps of: arranging a semiconductor chip so that its main surface faces upwards on a back-surface-side plate member via a conductive adhesive; arranging an elastic body on the main surface of the semiconductor chip via the conductive adhesive so as to elastically deform to a thickness direction of the semiconductor chip; arranging a main-surface-side plate member on the elastic body via the conductive adhesive; heating the conductive adhesive to connect the back-surface-side plate member, the semiconductor chip, the elastic member, and the main-surface-side plate member respectively; and sealing the back-surface-side plate member, the semiconductor chip, the elastic body, and the main-surface-side plate member while respectively pressing the plate member of the main-surface-side plate member from above and the plate member of the back-surface-side plate member from below.

The effects obtained by typical aspects of the present invention will be briefly described below.

In a molding process in the assembly of a semiconductor device, making a distance (L2) from a bottom surface of a cavity of a lower mold die to a ceiling surface of a cavity of an upper mold die of a resin molding die same as or shorter than a distance (L1) from a lower surface of a back-surface-side plate member to an upper surface of a main-surface-side plate member and arranging an elastic body between the main-surface-side plate member and the back-surface-side plate member can mitigate a load by a clamp pressure of mold die by an elastic deformation of the elastic member. Consequently, a load applied on a semiconductor chip is reduced, thereby preventing formation of cracks on a semiconductor chip and improving quality and reliability of products (semiconductor device).

Still further, the distance (L2) is made smaller than the L1min which is the smallest value of the assumed distance (L1), thereby preventing a resin from getting around to the upper surface side of the main-surface-side plate member in the molding process. Consequently, residual resin on the main-surface-side plate member can be prevented, and quality and reliability of products (semiconductor device) can be improved.

Moreover, in the case where a shape of a semiconductor chip is changed, it is possible to correspond by changing a shape of an elastic body which is easy to design and manufacture and also cheap without changing a shape of a main-surface-side plate member which requires time and cost for designing and manufacture. In other words, it is possible to complete a design change of a semiconductor device easily and cheaply even when a shape of a semiconductor chip is design-changed.

### BRIEF DESCRIPTIONS OF THE DRAWINGS

FIG. 1 is a cross-sectional view showing an example of a semiconductor device according to a first embodiment of the present invention;

FIG. 2 is a perspective view showing an example of an inner structure without resin of the semiconductor device shown in FIG. 1;

FIG. 3 is a perspective view showing an example of the structure shown in FIG. 2 without a main-surface-side plate member;

FIG. 4 is a planer view showing an example of a semiconductor element (insulated gate bipolar transistor) embedded in the semiconductor device shown in FIG. 1;

FIG. 5 is a back side view showing an example of the structure of the semiconductor element shown in FIG. 4;

FIG. 6 is a cross-sectional view showing an example of a state of wire connection of an external connection lead and a bonding pad of the semiconductor element in the structure shown in FIG. 3;

FIG. 7 is a planer view showing an example of a structure of a semiconductor element (diode) embedded in the semiconductor device shown in FIG. 1;

FIG. 8 is a back side view showing an example of the structure of the semiconductor element shown in FIG. 7;

FIG. 9 is a perspective view showing a structure of a modification example of the structure shown in FIG. 3;

FIG. 10 is a perspective view showing the other modification example of the structure shown in FIG. 3;

FIG. 11 is a side view showing an example of a structure of an elastic body embedded in the semiconductor device shown in FIG. 1;

FIG. 12 is a planer view showing an example of the elastic body shown in FIG. 11;

FIG. 13 is a planer view showing an example of a structure of a back-surface-side plate member embedded in the semiconductor device shown in FIG. 1;

FIG. 14 is a side view showing an example of the structure of the back-surface-side plate member shown in FIG. 13;

FIG. 15 is a perspective view showing an example of an external structure of the semiconductor device shown in FIG. 1;

FIG. 16 is a diagram showing a manufacturing process flow of an example of a procedure of an assembly of the semiconductor device shown in FIG. 1;

FIG. 17 is a cross-sectional view showing an example of a structure after assembling the main-surface-side plate member in the assembly of the semiconductor device shown in FIG. 1;

FIG. 18 is a cross-sectional view showing an example of a structure at a time of sealing in the assembly of the semiconductor device shown in FIG. 1;

FIG. 19 is a cross-sectional view showing an example of a structure after cutting a lead in the assembly of the semiconductor device shown in FIG. 1;

FIG. 20 is a cross-sectional view showing an example of a structure after mounting the elastic body in the assembly of the semiconductor device shown in FIG. 1;

FIG. 21 is a partial planer view showing an example of the structure shown in FIG. 20;

FIG. 22 is a cross-sectional view showing an example of a structure after mounting the main-surface-side plate member in the assembly of the semiconductor device shown in FIG. 1;

FIG. 23 is a partial planer view showing an example of the structure shown in FIG. 22;

FIG. 24 is a cross-sectional view showing an example of a structure after sealing in the assembly of the semiconductor device shown in FIG. 1;

FIG. 25 is a partial planer view showing an example of the structure shown in FIG. 24;

FIG. 26 is a cross-sectional view showing an example of a semiconductor device according to a second embodiment of the present invention;

FIG. 27 is a cross-sectional view showing an example of a semiconductor device according to a third embodiment of the present invention;

FIG. 28 is a cross-sectional view showing an example of a semiconductor device according to a fourth embodiment of the present invention;

FIG. 29 is a cross-sectional view showing a structure of a semiconductor device of a double-sided cooling structure according to a comparative example;

FIG. 30 is a cross-sectional view showing a structure at a time of sealing in an assembly of the semiconductor device according to the comparative example shown in FIG. 29; and

FIG. 31 is a cross-sectional view of the other structure at the time of sealing in the assembly of the semiconductor device according to the comparative example shown in FIG. 29.

### DESCRIPTIONS OF THE PREFERRED EMBODIMENTS

In the embodiments described below, the repetitive description of the same or similar components will be omitted unless it is needed.

Further, in the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Moreover, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Herein after, embodiments of the present invention will be described in detail with reference to the accompanying drawings. Note that components having the same function are denoted by the same reference symbols throughout the drawings for describing the embodiment, and the repetitive description thereof will be omitted. In the drawings used for describing embodiments, hatching may be used even in perspective views and planer views so as to make the drawings easy to see.

### First Embodiment

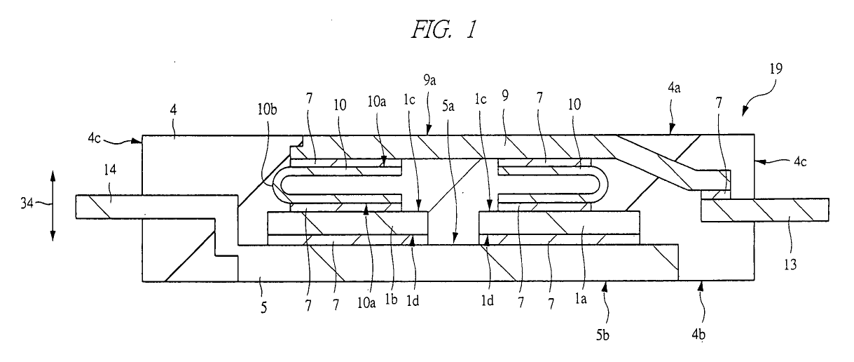

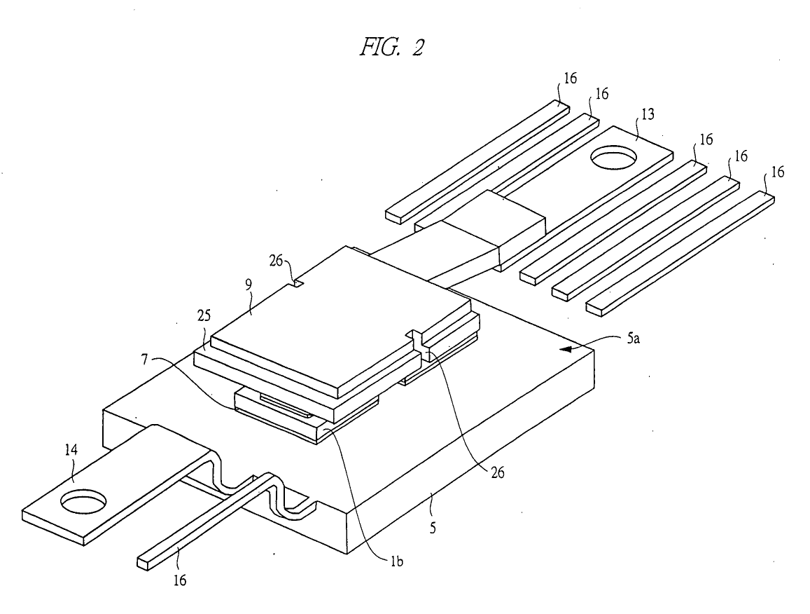

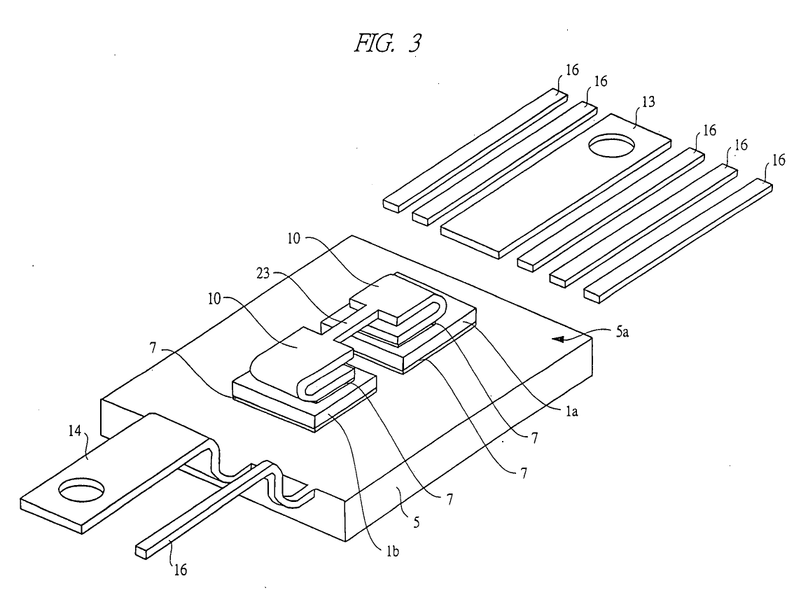

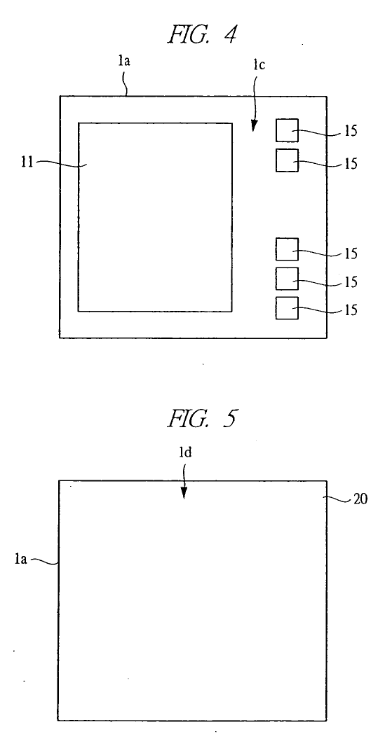

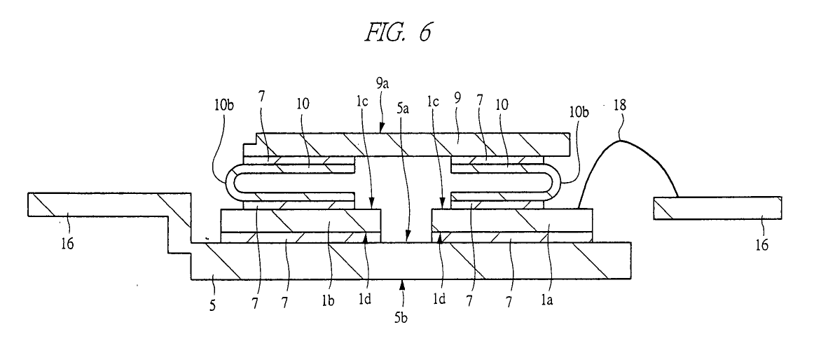

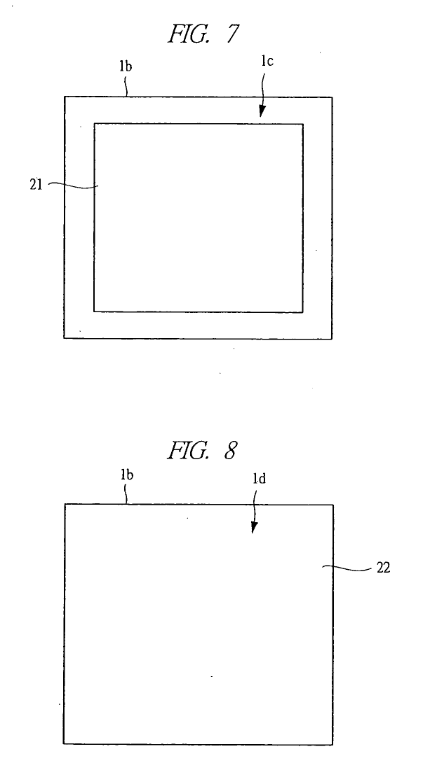

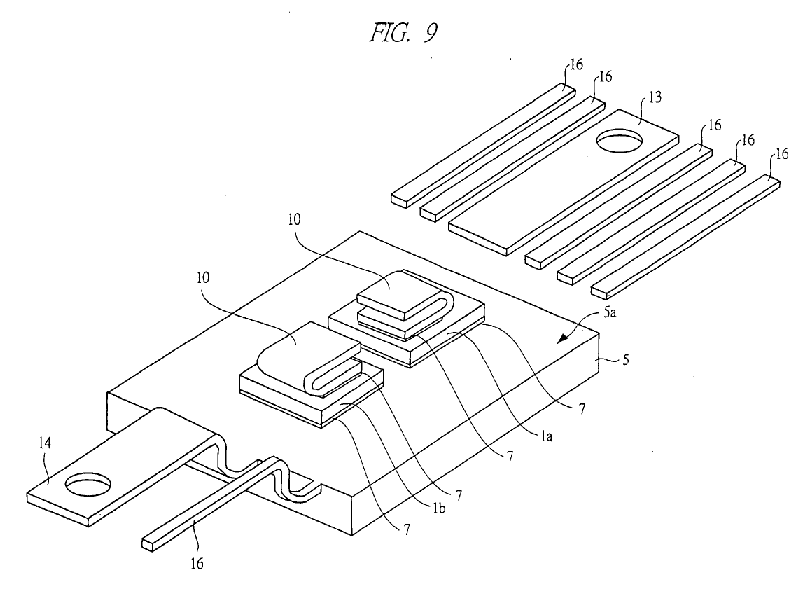

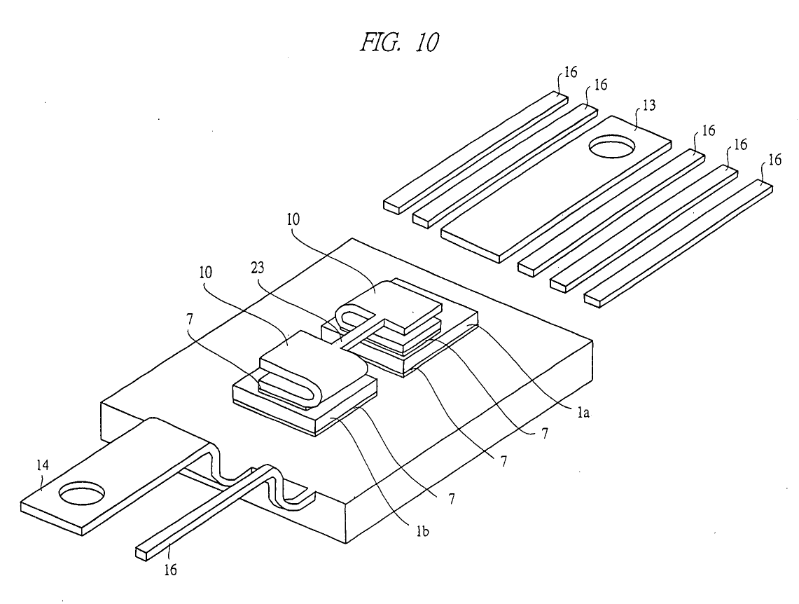

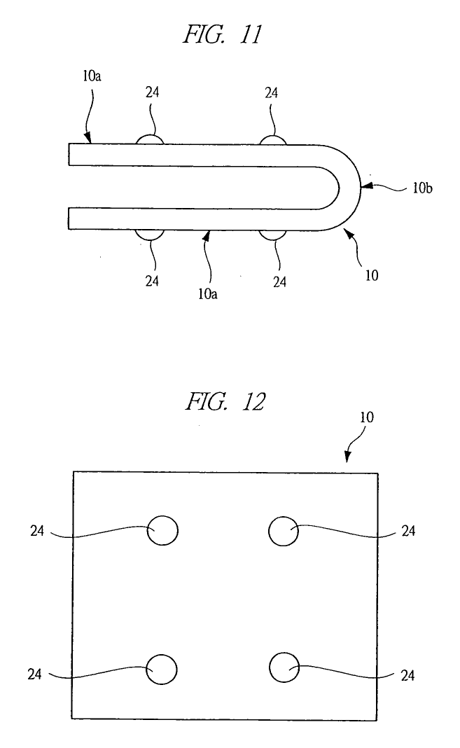

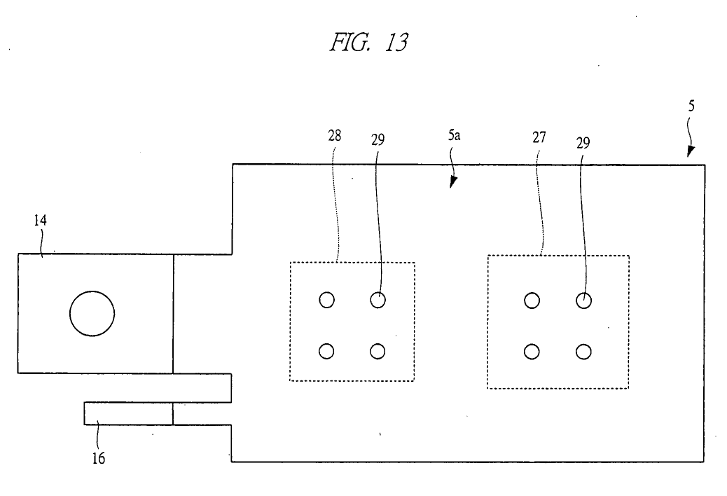

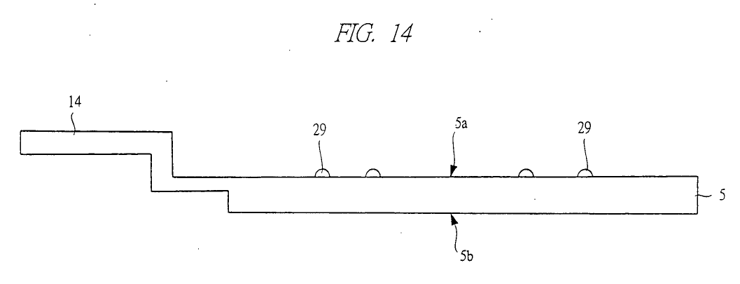

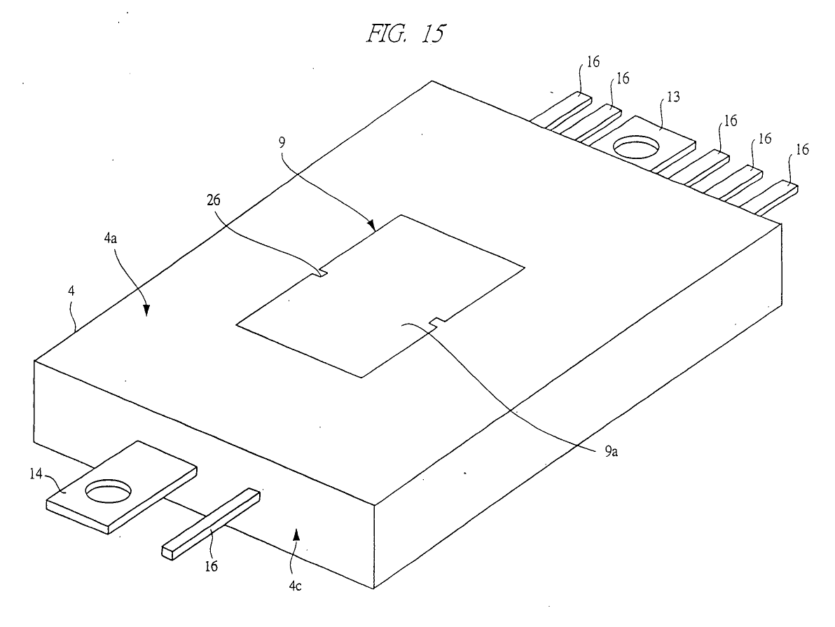

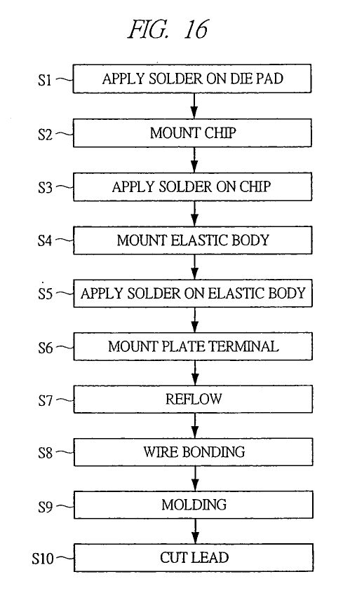

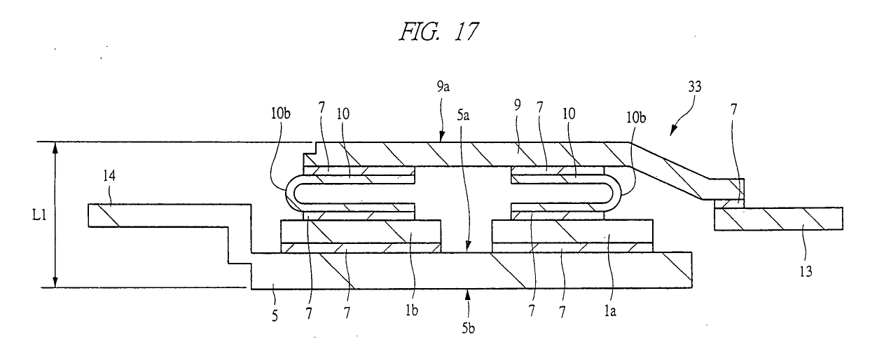

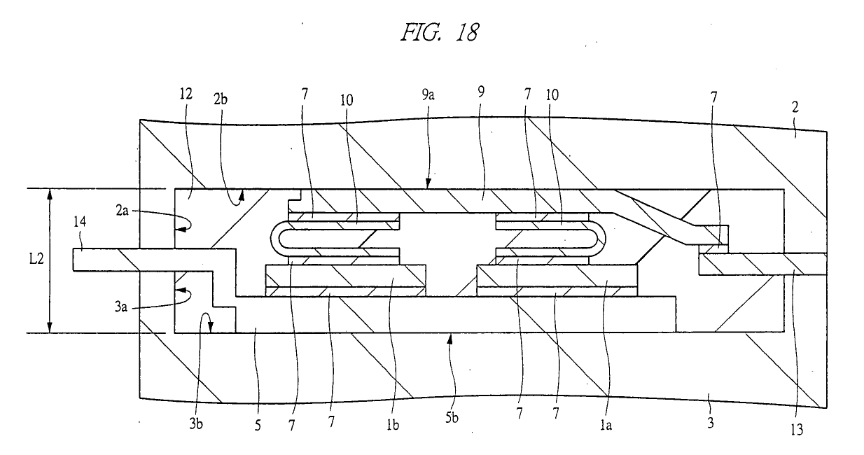

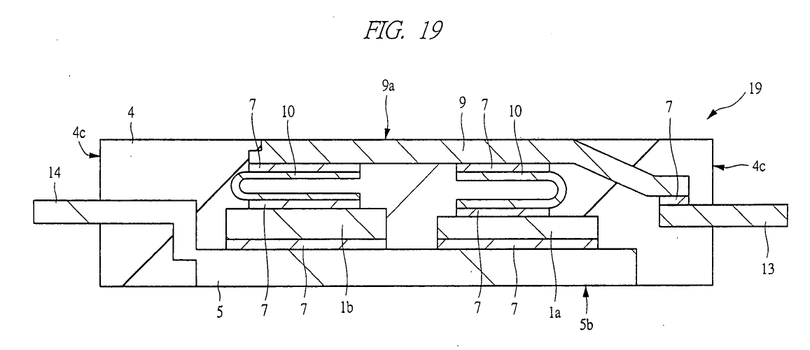

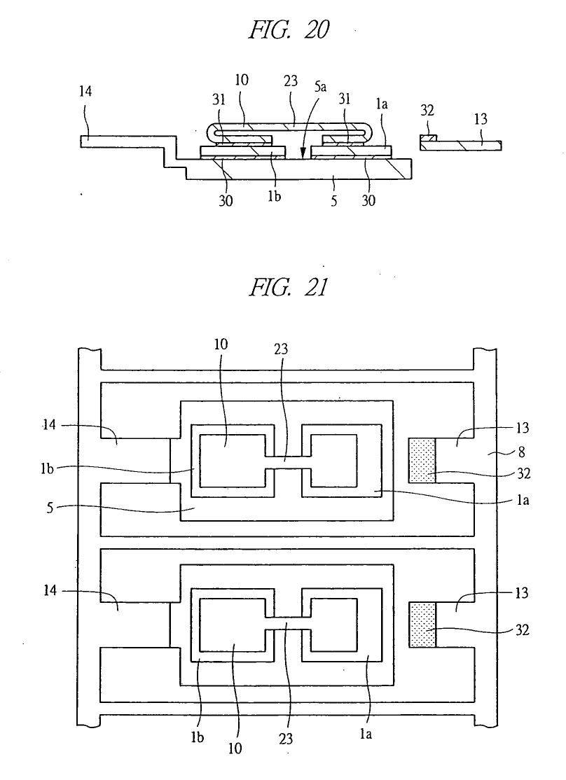

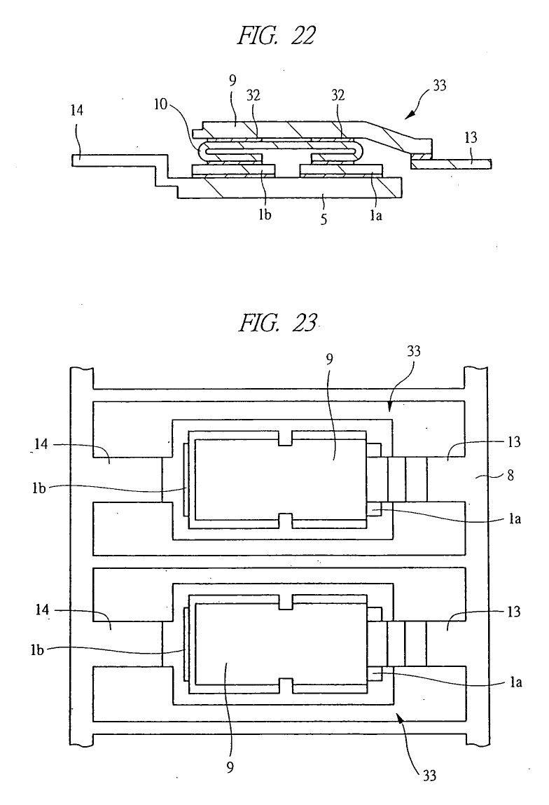

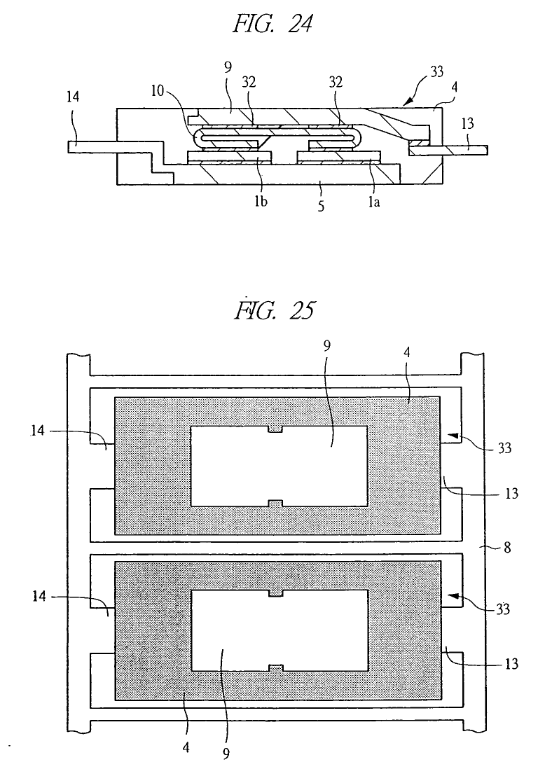

FIG. 1 is a cross-sectional view showing an example of a semiconductor device according to a first embodiment of the present invention, FIG. 2 is a perspective view showing an example of an inner structure without a resin of the semiconductor device shown in FIG. 1, FIG. 3 is a perspective view showing an example of the structure shown in FIG. 2 without a main-surface-side plate member, FIG. 4 is a planer view showing an example of a semiconductor element (Insulated Gate Bipolar Transistor) embedded in the semiconductor device shown in FIG. 1, and FIG. 5 is a back side view showing an example of the structure of the semiconductor element shown in FIG. 4. Further, FIG. 6 is a cross-sectional view showing an example of a state of wire connection of an external connection lead and a bonding pad of the semiconductor element in the structure shown in FIG. 3, FIG. 7 is a planer view showing an example of a structure of a semiconductor element (diode) embedded in the semiconductor device shown in FIG. 1, FIG. 8 is a back side view showing an example of the structure of the semiconductor element shown in FIG. 7, FIG. 9 is a perspective view showing a structure of a modification example of the structure shown in FIG. 3, and FIG. 10 is a perspective view showing the other modification example of the structure shown in FIG. 3. Still further, FIG. 11 is a side view showing an example of a structure of an elastic body embedded in the semiconductor device shown in FIG. 1, FIG. 12 is a planer view showing an example of the elastic body shown in FIG. 11, FIG. 13 is a planer view showing an example of a structure of a back-surface-side plate member embedded in the semiconductor device shown in FIG. 1, FIG. 14 is a side view showing an example of the structure of the back-surface-side plate member shown in FIG. 13, and FIG. 15 is a perspective view showing an example of an external structure of the semiconductor device shown in FIG. 1. Moreover, FIG. 16 is a diagram showing a manufacturing process flow of an example of a procedure of an assembly of the semiconductor device shown in FIG. 1, FIG. 17 is a cross-sectional view showing an example of a structure after assembling the main-surface-side plate member in the assembly of the semiconductor device shown in FIG. 1, FIG. 18 is a cross-sectional view showing an example of a structure at a time of sealing in the assembly of the semiconductor device shown in FIG. 1, FIG. 19 is a cross-sectional view showing an example of a structure after cutting leads in the assembly of the semiconductor device shown in FIG. 1, FIG. 20 is a cross-sectional view showing an example of a structure after mounting the elastic body in the assembly of the semiconductor device shown in FIG. 1, FIG. 21 is a partial planer view showing an example of the structure shown in FIG. 20, FIG. 22 is a cross-sectional view showing an example of a structure after mounting the main-surface-side plate member in the assembly of the semiconductor device shown in FIG. 1, and FIG. 23 is a partial planer view showing an example of the structure shown in FIG. 22. Finally, FIG. 24 is a cross-sectional view showing an example of a structure after sealing in the assembly of the semiconductor device shown in FIG. 1, and FIG. 25 is a partial planer view showing an example of the structure shown in FIG. 24.

A semiconductor device 19 according to the present first embodiment shown in FIG. 1 is a semiconductor package having a double-sided cooling structure capable of improving a heat transfer property. As shown in FIG. 1, the semiconductor device 19 comprises: a semiconductor element (semiconductor chip) 1a; a semiconductor element (semiconductor chip) 1b; a sealing body 4; a die pad (back-surface-side plate member) 5; a plate terminal (main-surface-side plate member) 9; an elastic body 10; an adhesive (conductive adhesive) 7; an emitter electrode for external connection 13; and a collector electrode for external connection 14.

Further, the semiconductor element 1a, the semiconductor element 1b, the die pad 5, the plate terminal 9, the elastic body 10, and the adhesive 7 are sealed by the sealing body 4, and among these, a lower surface 5b of the die pad 5 and an upper surface 9a of the plate terminal 9 are respectively exposed from the sealing body 4 of the semiconductor device 19.

Next, an entire schematic structure of the semiconductor device 19 will be described with reference to FIG. 1 to FIG. 9. The structure comprises: the semiconductor elements 1a and 1b which are semiconductor chips in which a main surface 1c and a back surface 1d opposite to the main surface 1c respectively have electrodes; the die pad 5 having the semiconductor elements 1a and 1b mounted thereon and connected to the electrode of the back surface 1d of the semiconductor elements 1a and 1b via the adhesive 7; the conductive elastic body 10 including opposing one and the other flat surfaces 10a and a bending part 10b coupling these flat surfaces 10a and arranged on the main surface 1c of the semiconductor elements 1a and 1b, and further connected to the electrode of the one flat surface 10a of the semiconductor elements 1a and 1b via the adhesive 7; the plate terminal 9 arranged on the elastic body 10 and connected to the other flat surface 10a of the elastic body via the adhesive 7; and the sealing body 4 for sealing the semiconductor elements 1a and 1b, the elastic body 10, the die pad 5, and the plate terminal 9.

Note that, as shown in FIG. 15, the plate terminal 9 has its upper surface 9a exposed from a ceiling surface 4a of the sealing body 4, and as shown in FIG. 1, the die pad 5 has its lower surface 5b exposed from a bottom surface 4b of the sealing body 4. In this manner, since respective parts of the plate terminal 9 and the die pad 5 are exposed from the sealing body 4, it is a double-sided cooling structure, thereby enabling an improvement of the heat-transfer property of the semiconductor device 19.

Further, in the present first embodiment 1, the elastic bodies 10 are formed in a U-shape as shown in FIG. 1 and arranged on the semiconductor elements 1a and 1b so as to cause an elastic action to a thickness direction 34 of the semiconductor elements 1a and 1b thereof. In other words, each elastic body 10 is arranged to have a direction of its U-shape opening facing to a direction along with the respective main surfaces 1c of the semiconductor elements 1a and 1b, and the opposing flat surfaces boa forming the U-shape are arranged so as to oppose to a height direction of the semiconductor device 19. In this manner, an elastic action is applied to the thickness direction (height direction of the semiconductor device 19) 34 of the respective semiconductor elements 1a and 1b so that causing an elastic deformation.

Next, the semiconductor element 1a mounted on the semiconductor device 19 will be described. To the semiconductor element 1a, for example, an IGBT (Insulated Gate Bipolar Transistor element) is formed. FIG. 4 is a planer view showing a configuration of the main surface (upper surface) side of the semiconductor element 1a. To the main surface 1c of the semiconductor element 1a, an emitter electrode 11 and a plurality of bonding pads (electrodes) 15 are formed.

Note that, as shown in FIG. 1, to the emitter electrode 11, the U-shape elastic body 10 is connected via the adhesive 7, and further, the emitter electrode 11 is connected to the emitter electrode for external connection 13 via the elastic body 10 and the plate terminal 9. And, the bonding pad 15 of the semiconductor element 1a is connected to the external connection lead 16 by using a wire 18 as shown in FIG. 6.

FIG. 5 is a planer view showing a configuration of the back surface side of the semiconductor element 1a, and on the back surface 1d, a collector electrode 20 is formed. The collector electrode 20 is, as shown in FIG. 1, connected to the die pad 5 via the adhesive 7 and connected to the collector electrode for external connection 14 that is formed integrally with the die pad 5.

As shown in FIG. 1 and FIG. 15, the emitter electrode for external connection 13, the collector electrode for external connection 14 and the external connection lead 16 respectively protrude to outside from the side surface 4c of the sealing body 4 and they are external terminals.

Next, the semiconductor element 1b mounted on the semiconductor device 19 will be described. To the semiconductor element 1b, for example, a diode element is formed. FIG. 7 is a planer view showing a configuration of the semiconductor element 1b at the main surface 1c (upper surface) side thereof. To the main surface 1c of the semiconductor element 1b, an anode electrode 21 is formed. The anode electrode 21 is connected to the emitter electrode for external connection 13 via the elastic body 10 and the plate terminal 9.

Further, as shown in FIG. 8, to the back surface (lower surface) 1d of the semiconductor element 1b, a cathode electrode 22 is formed. The cathode electrode 22 is connected to the die pad 5 via the adhesive 7 as shown in FIG. 1, and further connected to the collector electrode for external connection 14 that is formed integrally with the die pad 5.

Next, the elastic body 10 embedded in the semiconductor device 19 will be described. As shown in FIG. 1, the elastic body 10 of the present embodiment 1 is formed in a U-shape and respectively connected to the electrode parts (emitter electrode 11, anode electrode 21) of the main surface 1c of respective semiconductor elements 1a and 1b via the adhesive 7 of such as a solder material. At this time, on the respective semiconductor elements 1a and 1b, the elastic body 10 is arranged so as to have a direction of its U-shape opening facing to a direction along with the main surface 1c of the respective semiconductor elements 1a and 1b and so as to have the opposing flat surface 10a forming the U-shape opposing to the height direction of the semiconductor device 19. In this manner, an elastic action is applied to the thickness direction (height direction of the semiconductor device 19) of the respective semiconductor elements 1a and 1b.

Note that, inside of the elastic body 10 may be formed of a non-conductive material, and in this case, it is only necessary to cover the surface by a conductive plating and the like. In other words, while it is preferable for the elastic body 10 to be formed of a conductive material, it is not necessarily be formed by a conductive material and it is only necessary to cover at least the surface by a conductive plating and the like.

Further, the U-shape elastic body 10 arranged on each of the semiconductor elements 1a and 1b may be formed integrally via the lead material 23 as shown in FIG. 3 or separately on each of the semiconductor elements 1a and 1b as shown in FIG. 9 (FIG. 1). As shown in FIG. 1 and FIG. 9, when two or more semiconductor chips are mounted on the die pad 5, by arranging the elastic body 10 divided by each semiconductor chip on each semiconductor ship, even when a shape change such as a change in the thickness of the semiconductor chip is made, it is only necessary to change a shape of only the elastic body 10 on the shape-changed chip. In other words, to change the shape of only the elastic body 10 which is easy to design and manufacture and also inexpensive can deal with the situation without changing the shape of the plate terminal 9 which requires time and cost for design and manufacture.

Therefore, also in a design change of the shape of the semiconductor chip, it is possible to complete a design change of the semiconductor device 19 easily and inexpensively.

As to the semiconductor device 19 of the present first embodiment, the U-shape elastic bodies 10 arranged on the respective semiconductor elements 1a and 1b are preferable to be arranged so that their openings of the U-shape face opposite directions to each other.

More specifically, making the respective openings of the U-shape of the plurality of elastic bodies 10 arranged integrally or separately on respective chips face opposite directions to each other can prevent the plate terminal 9 arranged on the elastic body 10 from being positioned at a tilt. Note that, in this case, as shown in FIG. 3, forming the plurality of elastic bodies 10 integrally via the lead material 23 can make a direction of the bend of the elastic body 10 to be symmetric between chips, thereby forming the elastic body 10 easily and inexpensively.

Further, as shown in the modification example of FIG. 10, along with forming the elastic bodies 10 to be arranged on respective semiconductor chips 1a and 1b integrally via the lead material 23, the direction of the openings of the U-shape may be arranged by rotating 90 degrees from the direction shown in FIG. 3, and also in this case, same effects similar to those of the structure shown in FIG. 3 can be produced.

Here, a detailed structure of the elastic body 10 will be described with reference to FIG. 11 and FIG. 12. The elastic body 10 is formed in a U-shape and comprises opposing two flat surfaces 10a and a bending part 10b which associates the flat surfaces 10a, and the U-shape is formed by the opposing flat surfaces 10a and the bending part 10b. Further, on the surfaces of the flat surfaces 10a of the elastic body 10, four protrusions 24 are provided respectively on surfaces to be connected to the semiconductor chip and the plate terminal 9. Note that, the number of the protrusions 24 is only necessary to be at least three on each surface so that the elastic body 10 is stably held, and it is preferably four or more.

In the assembly of the semiconductor device 19, an assembly system is used where the adhesive 7 such as a solder material is applied respectively between the die pad 5, the semiconductor elements 1a and 1b, the plate terminal 9, and the elastic body 10 and the adhesive 7 is heated to melt so that respective parts are fixed. By the protrusions 24 provided on the flat surfaces 10a of the elastic body 10, it is possible to ensure the thickness of the adhesive 7 as same as or more than a height of the protrusions 24.

By ensuring the thickness of the adhesive 7 in this manner, the adhesive 7 can have an improved fatigue life. Note that, as a material of the elastic body 10, in order to improve its heat transfer property, for example, it is preferable to use a copper alloy and the like having a large thermal conductivity.

Next, the plate terminal (main-surface-side plate member) 9 will be described with reference to FIG. 1, FIG. 2 and FIG. 15. As shown in FIG. 1, the plate terminal 9 is connected to the flat surface 10a of the elastic body 10 via the adhesive 7, and as shown in FIG. 15, the upper surface 9a thereof is exposed from the ceiling surface of the sealing body 4. And, in order to improve adhesiveness between the plate terminal 9 and the sealing body 4 to prevent exfoliation, as shown in FIG. 2, a step part 25 is provided along a periphery of the plate terminal 9. Further, to an arbitral side which is exposed from the ceiling surface 4a of the sealing body 4, a notch 26 is provided. In other words, the step part 25 provided along the periphery of the plate terminal 9 enables a lock function with the sealing body 4 in a height direction of the package, and the notch 26 of the plate terminal 9 provided to an arbitral side exposed from the ceiling surface 4a of the sealing body 4 enables a lock function with the sealing body 4 in a horizontal direction of the package. Consequently, the plate terminal 9 can be prevented from dropping from the sealing body 4 in the height direction of the package and the horizontal direction of the package. Note that, the plate terminal 9 not necessarily be the part to provide the step part 25 and the notch 26 to.

Further, as a material of the plate terminal 9, in order to improve the heat transfer property, for example, it is preferable to use a copper alloy and the like having a large heat conductivity.

Next, the adhesive 7 will be described. The adhesive 7 is preferably, for example, a solder of tin (Sn), silver (Ag) and copper (Cu), and a solder of tin (Sn) and antimony (Sb). They are lead-free solders and it is very effective to the environment to make the composition of materials not include lead in an environmental consideration.

Next, the die pad 5 will be described with reference to FIG. 1, FIG. 13 and FIG. 14. As shown in FIG. 1, the die pad 5 has the semiconductor elements 1a and 1b on the upper surface 5a thereof, and the lower surface 5b thereof is exposed from the bottom surface 4b of the sealing body 4. And, as shown in FIG. 13 and FIG. 14, on the surface to mount elements which is the upper surface 5a of the die pad 5, a plurality of protrusions 29 are provided in element mounting parts 27 and 28. The number of the protrusions 29 is only necessary to be three or more on the each element mounting part 27 and 28, and when there are four or more protrusions 29, the respective semiconductor elements 1a and 1b can be stably held.

Further, by providing the protrusions 29 plurally, it is possible to ensure the thickness of the adhesive 7 to be used for the connection between the die pad 5 and the semiconductor elements 1a and 1b as same as or more than a height of the protrusion 29, thereby improving the fatigue life of the adhesive 7. Note that, as a material of the die pad 5, in order to improve the heat transfer property, for example, it is preferable to use a copper alloy and the like having a large thermal conductivity.

Next, the resin 12 for sealing which forms the sealing body 4 will be described with reference to FIG. 12 (cf., FIG. 18). As the resin 12, it is preferable to use, for example, a phenol-based curing agent, a silicone rubber, an epoxy-based thermosetting resin added with filler and the like. And, the sealing body 4 formed of the resin 12 is formed by a transfer molding suitable for mass production. Transfer molding uses a resin mold die (a mold die comprised of the lower mold die 3 and the upper mold die 2) comprising a pot, a runner, a resin injection gate and a cavity, and the sealing body 4 is formed by injecting the thermosetting resin 12 inside the cavity 2a and 3a from the pot through the runner and the resin injection gate.

Next, a method of assembly of the semiconductor device according to the present first embodiment will be described with reference to the process flow diagram of FIG. 16.

First, solder application is performed on the die pad as shown by a step S1 of FIG. 16. Here, as shown in FIG. 20, a die-pad adhesive (adhesive 7) 30 is applied to the upper surface 5a of the die pad 5, and then, chip mounting of a step S2 is performed. More specifically, semiconductor elements 1a and 1b are mounted on the die-pad adhesive 30 applied on two portions (the element mounting part 27 and 28 shown in FIG. 13). At this time, the semiconductor elements 1a and 1b are mounted on the die pad 5 so that the respective main surfaces 1c face upwards.

After that, solder application of a step S3 is performed on the chip, and further, elastic-body mounting of a step S4 is performed. Here, an elastic-body adhesive (adhesive 7) 31 is applied on the respective semiconductor elements 1a and 1b, and the elastic bodies 10 are mounted on the semiconductor elements 1a and 1b. At this time, the U-shape of the elastic body 10 is arranged laterally-facing so as to be elastically deformed by an elastic action to the thickness direction (height direction of package) of the semiconductor elements 1a and 1b.

After that, solder application is performed on the elastic body in a step S5, and further, plate-terminal mounting of a step S6 is performed. Here, as shown in FIG. 20 and FIG. 21, as well as applying a plate-terminal adhesive (adhesive 7) 32 on an edge part of the emitter electrode for external connection 13 of the lead frame 8, the plate-terminal adhesive 32 is applied on the elastic body 10 as shown in FIG. 22, and further, as shown in FIG. 22 and FIG. 23, the plate terminal 9 is mounted on the elastic body 10 and the emitter electrode for external connection 13.

After finishing mounting of the plate terminal 9, reflow as shown by a step S7 is performed to fix each component. Here, respective components are connected by performing batch reflow. More specifically, the die-pad adhesive 30, the elastic-body adhesive 31 and the plate-terminal adhesive 32 are melted by the batch reflow to connect respective components.

Thereafter, wire bonding as shown by a step S8 is performed. Here, as shown in FIG. 6, the electrode of the main surface 1c of the semiconductor element 1a (the bonding pad 15 shown in FIG. 14) and the external connection lead 16 are connected by the wire 18 such as a gold wire.

After the wire bonding, molding as shown by a step S9 is performed. Here, by the transfer molding, the semiconductor elements 1a and 1b, the elastic body 10, the die pad 5 and the plate terminal 9 are resin-sealed so that the sealing body 4 is formed. At this time, first, an assembled body 33 shown in FIG. 17 after the reflow and wire bonding is arranged on the lower mold die 3 shown in FIG. 18.

Further, after covering the assembled body 33 by the upper mold die 2, the lower mold die 3 and the upper mold die 2 are subjected to clamping to apply a clamp pressure. After that, the resin 12 for sealing is poured from an inlet not shown and resin sealing is performed to form the sealing body 4.

Note that, in the assembly of the semiconductor device 19 according to the present first embodiment, in the assembled body 33 shown in FIG. 17, the distance (L1) from the lower surface 5b of the die pad 5 to the upper surface 9a of the plate terminal 9 varies according to the thickness of the adhesive 7 and the process precision of the elastic body 10. Here, the minimum value of (L1) considering the variation of (L1) is taken as (L1)min, and taking a distance (L2) from the bottom surface 3b of the cavity 3a of the lower mold die 3 to the ceiling surface 2b of the cavity 2a of the upper mold die 2 upon clamping of the lower mold die 3 and the upper mold die 2, in the assembly of the semiconductor device 19, the distance (L2) is set to be a same value as the distance (L1) or equal to or lower than (L1)min.

In this case, from the upper mold die 2 to the plate terminal 9 and also from the lower mold die 3 to the die pad 5, while a pressure is applied respectively, the resin 12 for sealing is filled in the cavities 2a and 3a. As a procedure from mold-die clamping (clamping) to resin filling, the die pad 5 is contacted to the bottom surface 3b of the cavity 3a of the lower mold die 3, and the plate terminal 9 is contacted to the ceiling surface 2b of the cavity 2a of the upper mold die 2, after that, while pressing respective plate members (die pad 5 and plate terminal 9) from the upper part of the plate terminal 9 and the lower part of the die pad 5, the resin 12 is filled in the cavities 2a and 3a so that the die pad 5, he semiconductor elements 1a and 1b, the elastic body 10, and the plate terminal 9 are resin-sealed. Consequently, the sealing body 4 is formed so as to expose the lower surface 5b of the die pad 5 and the upper surface 9a of the plate terminal 9.

Note that, in the resin filling, while a clamp pressure is loaded on the semiconductor elements 1a and 1b via the plate terminal 9, the elastic body 10 and the die pad 5, at that time, this load is mitigated by the bending part 10b of the elastic body 10 deformed by an elastic action. In other words, the elastic body 10 is elastically deformed to the height direction of the package (thickness direction of the semiconductor chip 34).

Moreover, since the ceiling surface 2b of the cavity 2a of the upper mold die 2 is surely contacted with the plate terminal 9, in the resin filling, the resin 12 is prevented from getting around the upper surface 9a side of the plate terminal 9. In this manner, by providing the elastic body 10 having the bending part 10b whose elastic modulus gets smaller in a vertical direction (height direction of the package, thickness direction of the semiconductor chip 34), cracks of the semiconductor elements 1a and 1b can be prevented, and moreover, generation of defects of the semiconductor device 19 due to residual resin to the upper surface 9a of the plate terminal 9 can be prevented.

Further, as shown in FIG. 19, when the size such as thickness of the semiconductor element 1b is changed, it is possible to deal only by changing the shape of the elastic body 10, and it is not necessary to change the shape of the plate terminal 9. This unnecessity of the change in the shape of the plate terminal 9 which requires a large amount of time and cost and often associated with bending process and etching can make a benefit for shortening the design period of the semiconductor device 19.

After forming the sealing body 4, the upper mold die 2 and the lower mold die 3 are opened and the assembled body 33 is took out as shown in FIG. 24 and FIG. 25.

After finishing molding of a step S9 of FIG. 16, lead cutting of a step S10 is performed. Herein, dicing is performed by cutting the lead frame 8. More specifically, lead cuttings of the emitter electrode for external connection 13 and the collector electrode for external connection 14 are done by the lead frame 8 so that the assembly of the semiconductor device 19 is completed.

According to the semiconductor device and the assembly thereof according to the present first embodiment, the distance (L2) from the bottom surface 3b of the cavity 3a of the lower mold die 3 to the ceiling surface 2b of the cavity 2a of the upper mold die 2 of the resin mold die is made to be same or smaller than the distance (L1) from the lower surface 5b of the die pad 5 to the upper surface 9a of the plate terminal 9 of the assembled body 33, and further, the elastic body 10 is arranged on the semiconductor elements 1a and 1b on between the die pad 5 and the plate terminal 9, thereby mitigating the load of mold clamp pressure of the resin mold die by the elastic deformation of the elastic body 10.

Consequently, the load on the semiconductor elements 1a and 1b are reduced and thus formation of cracks on the semiconductor elements 1a and 1b can be prevented, thereby improving the quality and reliability of the product (semiconductor device 19).

Further, by making the distance (L2) have a value same as or smaller than the minimum value (L1)min of the predicted height (L1), upon filling of the resin in the molding process, the ceiling surface 2b of the cavity 2a of the upper mold die 2 and the upper surface 9a of the plate terminal 9 are surely contacted, thereby preventing the resin 12 from getting around the upper surface 9a side of the plate terminal 9.

As a result, residual resin on the plate terminal 9 can be prevented and the quality and reliability of the product (semiconductor device 19) can be improved.

Moreover, also in the case of changing shape such as the thickness of the semiconductor element 1a and the semiconductor element 1b, without changing the shape of the plate terminal 9 which requires a large amount of time and cost for design and manufacturing, by changing the shape of the elastic body 10 which is easy to design and manufacture and also inexpensive, it is possible to deal with the shape change of the semiconductor element 1a and the semiconductor element 1b. In other words, it is possible to complete a design change of the semiconductor device 19 easily and quickly and also inexpensively corresponding to a design change of the semiconductor element 1a and the semiconductor element 1b.

### Second Embodiment

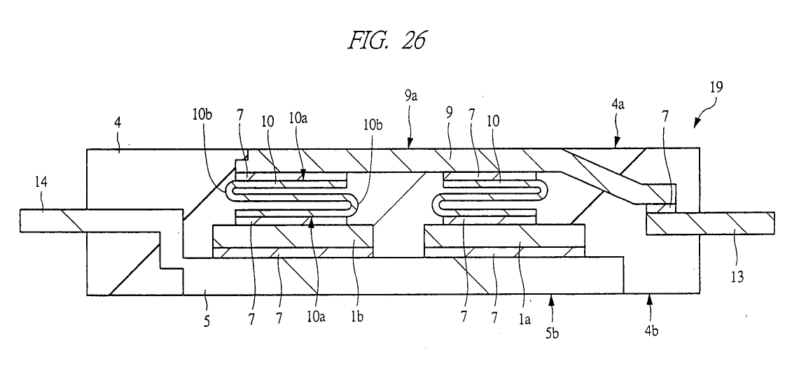

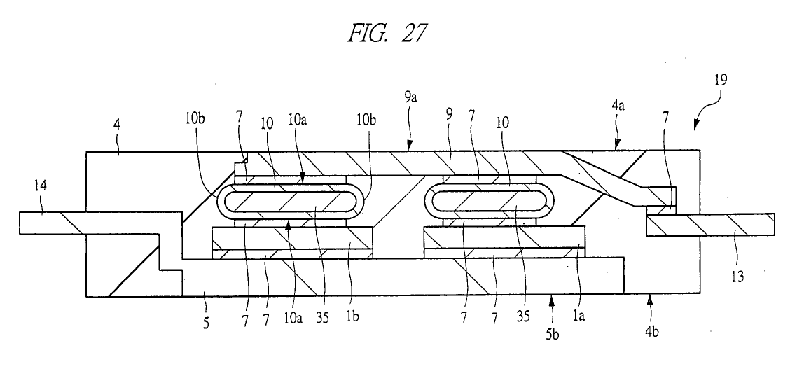

FIG. 26 is a cross-sectional view showing an example of a structure of a semiconductor device according to a second embodiment of the present invention.

The semiconductor device of the present second embodiment is, similarly to the first embodiment, the semiconductor device 19 having a configuration comprising: the semiconductor element 1a; the semiconductor element 1b; the sealing body 4; the die pad 5; the plate terminal 9; the elastic body 10; the adhesive 7; the emitter electrode for external connection 13; and the collector electrode for external connection 14 and so forth. A different point from the semiconductor device of the first embodiment is that the elastic bodies 10 arranged on the semiconductor devices 1a and 1b are formed in an S-shape respectively.

Thus, also when the elastic body 10 is formed in an S-shape, similarly to the first embodiment, the clamp pressure in the molding process can be mitigated by the deformation of the elastic body 10, thereby obtaining similar effects as those of the semiconductor device 19 of the first embodiment.

Further, since the elastic body 10 is formed in an S-shape, the portions to be elastically deformed are distributed to a plurality of portions, and thus the load applied to the respective semiconductor elements 1a and 1b is distributed rather than one portion as compared to the elastic body 10 in a U-shape of the first embodiment, thereby further reducing formation of cracks on the semiconductor elements 1a and 1b.

### Third Embodiment

FIG. 27 is a cross-sectional view showing an example of a structure of a semiconductor device according to a third embodiment of the present invention.

The semiconductor device of the present third embodiment is, similarly to the first embodiment, the semiconductor device 19 having a configuration comprising: the semiconductor element 1a; the semiconductor element 1b; the sealing body 4; the die pad 5; the plate terminal 9; the elastic body 10; the adhesive 7; the emitter electrode for external connection 13; and the collector electrode for external connection 14 and so forth. A different point from the semiconductor device of the first embodiment is that the elastic bodies 10 arranged on the semiconductor elements 1a and 1b are formed in a ring-shape respectively. Note that, in the ring-shape elastic body 10, a surface to be connected to the plate terminal 9 and the semiconductor elements 1a and 1b are the flat surfaces 10a, thereby improving the connectivity. Further, the elastic body 10 may be a tubular one as long as its cross-sectional shape is a ring.

Moreover, in the ring of the ring-shape elastic body 10, a first material 35 which has a thermal conductivity larger than that of the resin 12 and a smaller elastic modulus than that of a material forming the elastic body 10 (e.g., copper alloy) may be filled previously. The first material 35 is, for example, a silver paste.

Also when the elastic body 10 is formed in a ring-shape, similarly to the first embodiment, the clamp pressure in the molding process can be mitigated by the deformation of the elastic body 10, thereby obtaining similar effects as those of the semiconductor device 19 of the first embodiment.

Further, since the elastic body 10 is formed in a ring shape, potions to be elastically deformed are distributed to a plurality of portions similarly to the S-shape of the second embodiment, and thus the load applied to the respective semiconductor elements 1a and 1b is distributed rather than one portion as compared to the elastic body 10 in a U-shape of the first embodiment, thereby further reducing formation of cracks on the semiconductor elements 1a and 1b.

Moreover, by filling the first material 35, for example, a silver paste having a thermal conductivity smaller than that of the resin 12 in the ring of the ring-shape elastic body 10, the heat transfer property of the semiconductor device 19 can be further improved.

### Fourth Embodiment

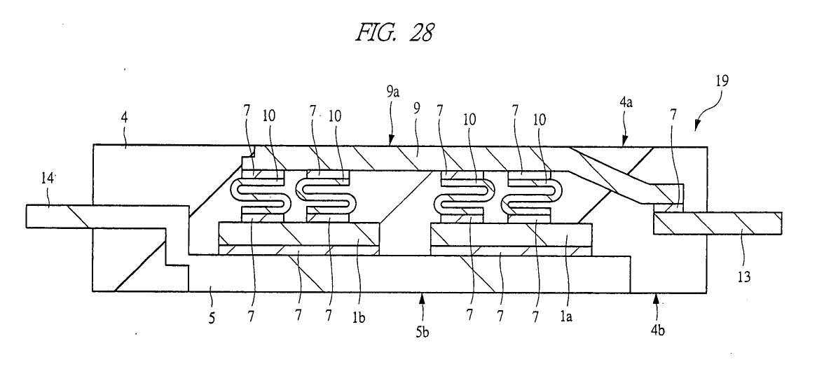

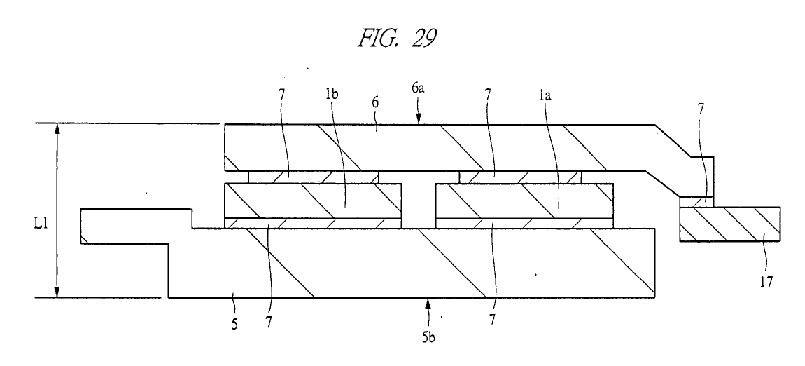

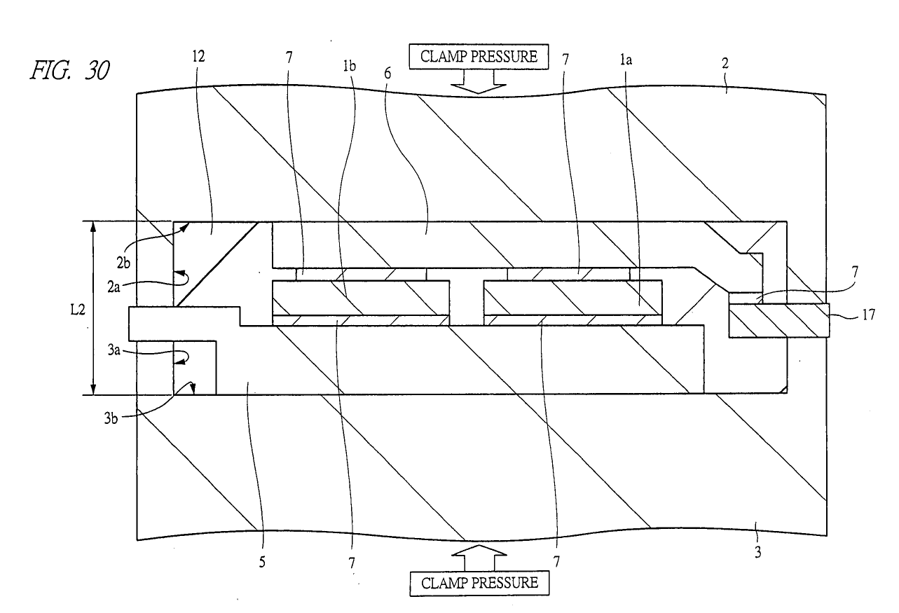

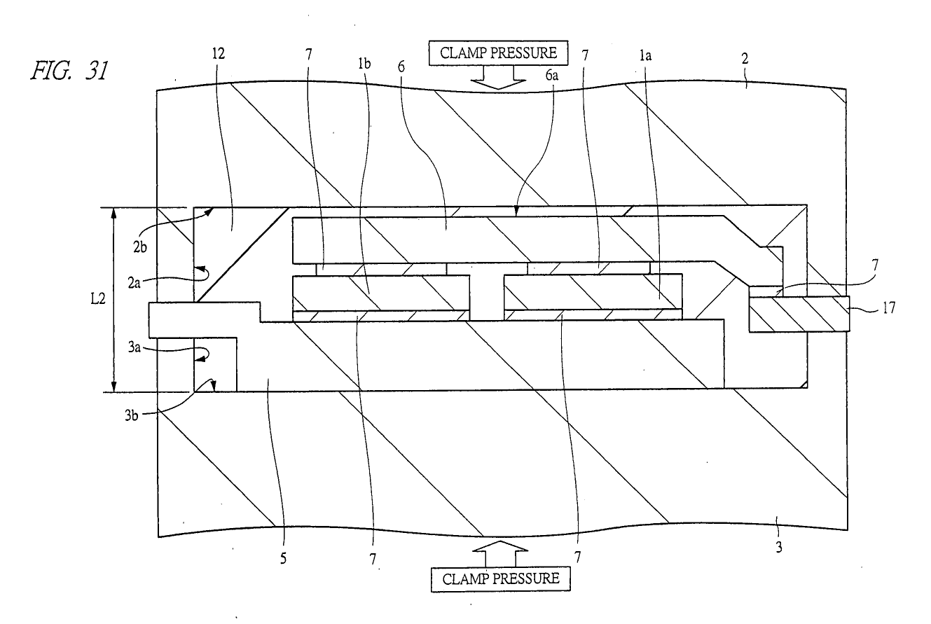

FIG. 28 is a cross-sectional view showing an example of a structure of a semiconductor device according to a fourth embodiment of the present invention.

The semiconductor device of the fourth embodiment is, similarly to the first embodiment, the semiconductor device 19 having a configuration comprising: the semiconductor element 1a; the semiconductor element 1b; the sealing body 4; the die pad 5; the plate terminal 9; the elastic body 10; the adhesive 7; the emitter electrode for external connection 13; and the collector electrode for external connection 14 and so forth. A different point from the semiconductor device of the first embodiment is that the elastic bodies 10 arranged on the semiconductor elements 1a and 1b are compact ones, and accordingly, a plurality of them are arranged on respective elements, and the respective compact elastic bodies 10 are formed in an S-shape.

Also when the plurality of compact elastic bodies 10 are arranged on the elements and formed in an S-shape, since portions to be elastically deformed are further distributed to a plurality portions, the load applied to the respective semiconductor elements 1a and 1b is distributed rather than one portion as compared to the elastic body 10 in a U-shape of the first embodiment. And as a result, formation of cracks of the semiconductor elements 1a and 1b can be further reduced.

Note that, even when the shape of the elastic body 10 is in such as a U-shape and ring-shape (or tubular-shape), two or more of the elastic bodies 10 can be arranged on the respective semiconductor devices 1a and 1b.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, in the above-described first to fourth embodiments, cases where two semiconductor elements are mounted on the semiconductor device 19 have been taken up and described. Meanwhile, the number of the semiconductor elements to be mounted may be one, or three or more.

Further, a adhesion area of the adhesive 7 to the elastic body 10 is not necessarily be the entire surface of the flat surface 10a, and it may be adhered to a part of the flat surface 10a.

The present invention is suitable for an electronic device of high thermal performance.

What is claimed is:

1. A semiconductor device comprising:
a semiconductor chip having a main surface and a back surface opposing the main surface, on which electrodes are respectively formed;
a back-surface-side plate member having the semiconductor chip mounted thereon and connected to the electrode of the back surface of the semiconductor chip via a conductive adhesive;
a conductive elastic body arranged on the main surface of the semiconductor chip and connected to the electrode of the main surface via a conductive adhesive;
a main-surface-side plate member arranged on the elastic body and connected to the elastic body via a conductive adhesive; and
a sealing body for sealing the semiconductor chip, the elastic body, the back-surface-side plate member and the main-surface-side plate member,
wherein the main-surface-side plate member is exposed from a ceiling surface of the sealing body and the back-surface-side plate member is exposed from a bottom surface of the sealing body, and
the elastic body is arranged so as to cause an elastic deformation to a thickness direction of the semiconductor chip.

2. The semiconductor device according to claim 1,
wherein two semiconductor chips are mounted on the back-surface-side plate member, the elastic body is formed in a U-shape, and the elastic bodies on the semiconductor chips are respectively arranged so that the respective U-shape openings thereof face opposite directions to each other.

3. The semiconductor device according to claim 1,
wherein one or a plurality of semiconductor chips are mounted on the back-surface-side plate member, and the elastic body divided by each of the semiconductor chips is arranged on the each semiconductor chip.

4. The semiconductor device according to claim 1,
wherein the elastic body is formed in an S-shape.

5. The semiconductor device according to claim 1,
wherein the elastic body is formed in a ring shape or a tubular shape.

6. The semiconductor device according to claim 5,
wherein, in the ring of the ring-shape elastic body, a first material having a thermal conductivity larger than that of a resin that forms the sealing body and smaller than that of a member that forms the elastic body is filled.

7. The semiconductor device according to claim 6,
wherein the elastic body is formed of a copper alloy, and the first material is a silver paste.

8. The semiconductor device according to claim 1,
wherein two semiconductor chips are mounted on the back-surface-side plate member, and one of the semiconductor chip includes an Insulated Gate Bipolar Transistor and the other semiconductor chip includes a diode element.

9. A semiconductor device comprising:
a semiconductor chip having a main surface and a back surface opposite to the main surface, on which electrodes are respectively formed;
a back-surface-side plate member having the semiconductor chip mounted thereon and connected to the electrode of the back surface of the semiconductor chip via a conductive adhesive;
a conductive elastic body including opposing one and the other flat surfaces and a bending part coupling the opposing one and the other flat surfaces and arranged on the main surface of the semiconductor chip, in which the one flat surface is connected to the electrode of the main surface of the semiconductor chip via a conductive adhesive;
a main-surface-side plate member arranged on the elastic body and connected to the other flat surface of the elastic body via a conductive adhesive; and
a sealing body for sealing the semiconductor chip, the elastic body, the back-surface-side plate member and the main-surface-side plate member,
wherein the main-surface-side plate member is exposed from a ceiling surface of the sealing body and the back-surface-side plate member is exposed from a bottom surface of the sealing body, and
the elastic body is arranged so as to cause an elastic deformation to a thickness direction of the semiconductor chip.

10. The semiconductor device according to claim 9,
wherein two semiconductor chips are mounted on the back-surface-side plate member; the elastic body is formed in a U-shape; and the elastic bodies on the semiconductor chips are respectively arranged so that the U-shape respective openings thereof face opposite directions to each other.

11. The semiconductor device according to claim 9,
wherein one or a plurality of semiconductor chips are mounted on the back-surface-side plate member, and the elastic body divided by each of the semiconductor chips is arranged on the each semiconductor chip.

12. The semiconductor device according to claim 9,
wherein the elastic body is formed in an S-shape.

13. The semiconductor device according to claim 9,
wherein the elastic body is formed in a ring shape or a tubular shape.

14. The semiconductor device according to claim 13,
wherein, in the ring of the ring-shape elastic body, a first material having a thermal conductivity larger than that of a resin that forms the sealing body and smaller than that of a member hat forms the elastic body is filled.

15. A method of manufacturing a semiconductor device comprising the steps of:
(a) arranging a semiconductor chip on a back-surface-side plate member via a conductive adhesive, so that its main surface faces upwards;
(b) arranging an elastic body on a main surface of the semiconductor chip via a conductive adhesive so as to cause an elastic deformation to a thickness direction of the semiconductor chip;
(c) arranging a main-surface-side plate member on the elastic body via a conductive adhesive;
(d) connecting the back-surface-side plate member, the semiconductor chip, the elastic member, and the main-surface-side plate member respectively by heating the conductive adhesive; and
(e) sealing the back-surface-side plate member, the semiconductor chip, the elastic body, and the main-surface-side plate member while respectively pressing the plate member of the main-surface-side plate member from above and the plate member of the back-surface-side plate member from below.

16. The semiconductor device according to claim 15,
wherein, in the step of (e), the back-surface-side plate member is contacted with a bottom surface of a cavity of a lower mold die for molding and the main-surface-side plate member is contacted with a ceiling surface of a cavity of an upper mold die for molding as well, and after that, while pressures are respectively applied to the main-surface-side plate member from the upper mold die and to the back-surface-side plate member from the lower mold die, and a resin for molding is filled in the cavities, thereby forming a sealing body.

17. The semiconductor device according to claim 16,
wherein, in the step of (e), a distance from a bottom surface of the cavity of the lower mold die to a ceiling surface of the cavity of the upper mold die after clamping by the lower mold die and the upper mold die is as same as or shorter than a distance from a lower surface of the back-surface side plate member to an upper surface of the main-surface-side plate member.
